(19) United States
(12) Patent Application Publication
(10) Pub. No.: US 2025/0316318 A1
(43) Pub. Date: Oct. 9, 2025

(54) MEMORY DEVICE AND OPERATION METHOD THEREOF

(71) Applicant: SAMSUNG ELECTRONICS CO., LTD., Suwon-si (KR)

(72) Inventors: JONGHOON PARK, Suwon-si (KR); JAE-DUK YU, Suwon-si (KR); SANG SOO PARK, Suwon-si (KR); SU CHANG JEON, Suwon-si (KR); Daein LEE, Suwon-si (KR)

(73) Assignee: SAMSUNG ELECTRONICS CO., LTD., Suwon-si (KR)

(21) Appl. No.: 19/040,550

(22) Filed: Jan. 29, 2025

(30) Foreign Application Priority Data
Apr. 8, 2024 (KR) 10-2024-0047172

(51) Int. Cl. G11C 16/34; G11C 16/08; G11C 16/10; G11C 16/30; G11C 29/12

(52) U.S. Cl. CPC G11C 16/3459; G11C 16/10; G11C 29/12005; G11C 16/08; G11C 16/30; G11C 2029/1202

(57) ABSTRACT

A method of operating a memory device which includes a memory circuit, is provided. The method includes: receiving a program command, an address, and data from a controller; and performing a program operation on a selected word line corresponding to the address according to the program command to store the data. The program operation includes: applying a first program voltage to the selected word line; applying a first verify voltage and a second verify voltage to the selected word line based on device information stored in the memory circuit; and detecting an error status of the device information stored in the memory circuit, based on a level difference of the first verify voltage and the second verify voltage.

### CROSS-REFERENCE TO RELATED APPLICATION

This application claims priority under 35 U.S.C. § 119 to Korean Patent Application No. 10-2024-0047172, filed on Apr. 8, 2024, in the Korean Intellectual Property Office, the disclosure of which is incorporated by reference herein in its entirety.

### BACKGROUND

The present disclosure described relates to a semiconductor memory, and more particularly, relates to a memory device and an operation method thereof.

A semiconductor memory may be classified as a volatile memory, which loses data stored therein when a power is turned off, such as a static random access memory (SRAM) or a dynamic random access memory (DRAM), or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

A flash memory may be used as a high-capacity storage medium. The flash memory operates based on various operation information or device information. In this case, the operation information or device information is stored in a memory circuit included in the flash memory. As the degree of integration of the flash memory increases, the size of the memory circuit included in the flash memory is decreasing. As the size of the memory circuit decreases, various errors occur in data stored in the memory circuit. When an error occurs in device information stored in the memory circuit, the flash memory may be incapable of operating normally. Accordingly, there is a need for detecting and recovering an error of data stored in the memory circuit.

### SUMMARY

One or more example embodiments provide a memory device with improved reliability and an operation method thereof.

According to an aspect of an example embodiment, a method of operating a memory device which includes a memory circuit, includes: receiving a program command, an address, and data from a controller; and performing a program operation on a selected word line corresponding to the address according to the program command to store the data. The program operation includes: applying a first program voltage to the selected word line; applying a first verify voltage and a second verify voltage to the selected word line based on device information stored in the memory circuit; and detecting an error status of the device information stored in the memory circuit, based on a level difference of the first verify voltage and the second verify voltage.

According to another aspect of an example embodiment, a memory device includes: a memory circuit configured to store device information; a memory cell array including a plurality of memory cells connected to a plurality of word lines; a control logic circuit configured to generate a first verify code and a second verify code, based on the device information, during a program verify operation; a voltage generating circuit configured to generate a first verify voltage based on the first verify code and generate a second verify voltage based on the second verify code, during the program verify operation; a row address decoder configured to apply the first verify voltage and the second verify voltage to a selected word line among the plurality of word lines, during the program verify operation; and an error checker circuit configured to detect an error status of the device information, based on a level difference of the first verify code and the second verify code, during the program verify operation.

According to another aspect of an example embodiment, a method of operating a memory device which includes a memory circuit, includes: receiving a program command, an address, and data from a controller; and sequentially performing a plurality of program loops on a selected word line corresponding to the address to perform a program operation of storing the data, according to the program command Each of the plurality of program loops includes: applying a program voltage to the selected word line to control threshold voltages of selected memory cells connected to the selected word line; applying verify voltages to the selected word line to verify a program state of the selected memory cells; and detecting an error status of device information stored in the memory circuit, based on a level difference of the verify voltages.

### BRIEF DESCRIPTION OF DRAWINGS

The above and other aspects and features will be more apparent from the following description of example embodiments, taken in conjunction with the accompanying drawings.

FIG. 1 is a diagram illustrating a storage device according to an example embodiment.

FIG. 2 is a block diagram illustrating a memory device according to an example embodiment.

FIGS. 3 and 4 are distribution diagrams for describing a program operation of a memory device according to an example embodiment.

FIG. 5 is a flowchart illustrating an operation of a memory device according to an example embodiment.

FIG. 6 is a diagram for describing a plurality of program loops according to an example embodiment.

FIG. 7 is a diagram for describing verify voltages used in each of a plurality of program loops according to an example embodiment.

FIG. 8A is a flowchart illustrating an operation of detecting an error status of the device information according to an example embodiment.

FIG. 8B is a diagram for describing an operation of detecting an error status of the device information according to an example embodiment.

FIG. 9 is a block diagram for describing a configuration of an error checker circuit according to an example embodiment of FIG. 2.

FIG. 10A is a flowchart illustrating an operation of detecting an error status of the device information according to an example embodiment.

FIG. 10B is a diagram for describing an operation of detecting an error status of the device information according to an example embodiment.

FIG. 11A is a flowchart for describing an operation of detecting an error status of the device information according to an example embodiment.

FIG. 11B is a diagram for describing an operation of detecting an error status of the device information according to an example embodiment.

FIG. 12A is a flowchart illustrating an operation of a memory device according to an example embodiment.

FIGS. 12B and 12C are diagrams for describing an operation of a memory device according to an example embodiment.

FIG. 13 is a flowchart illustrating an operation of a memory device according to an example embodiment.

FIGS. 14A and 14B are diagrams for describing an operation of a memory device according to an example embodiment.

FIG. 15 is a flowchart illustrating an operation of a storage device according to an example embodiment.

FIG. 16 is a view for describing a memory device according to an example embodiment.

### DETAILED DESCRIPTION

Below, example embodiments will be described with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

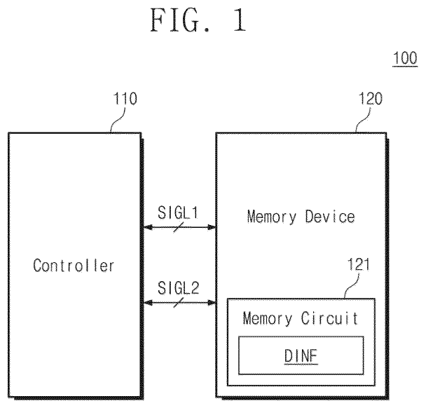

FIG. 1 is a diagram illustrating a storage device according to an example embodiment. Referring to FIG. 1, a storage device 100 may include a controller 110 and a memory device 120. In an example embodiment, the storage device 100 may be a high-capacity storage device, which is configured to store data in a computing system, such as a solid state drive (SSD) or a universal flash storage (UFS) card, but example embodiments are not limited thereto. Alternatively, the storage device 100 may be included in a mobile system such as a mobile phone, a smart phone, a tablet personal computer (PC), a wearable device, a health care device, or an Internet of things (IOT) device. Alternatively, the storage device 100 may be included in a personal computer, a laptop computer, a server, a media player, or an automotive device such as a navigation system.

The controller 110 may be configured to control the memory device 120. For example, the memory controller 110 may store data in the memory device 120 or may read data stored in the memory device 120. For example, the controller 110 may transmit a command CMD and an address ADDR to the memory device 120 through first signal lines SIGL1 and may exchange data “DATA” with the memory device 120 through the first signal lines SIGL1. In an example embodiment, the first signal lines SIGL1 may be data signal lines (e.g., DQ lines). The controller 110 may transmit control signals CTRL to the memory device 120 through second signal lines SIGL2. In an example embodiment, the control signals CTRL may be used to classify signals exchanged through the first signal lines SIGL1 into the command CMD, the address ADDR, and the data “DATA”. However, example embodiments are not limited thereto.

The memory device 120 may operate under control of the controller 110. For example, in response to signals received from the controller 110, the memory device 120 may store data or may output the stored data. In an example embodiment, the memory device 120 may include a NAND flash memory device, but example embodiments are not limited thereto. For example, the memory device 120 may include various memories such as a dynamic random access memory (DRAM), a static RAM (SRAM), a phase-change RAM (PRAM), a magnetic RAM (MRAM), a resistive RAM (RRAM), or a ferroelectric RAM (FRAM).

In an example embodiment, the above communication manner of the controller 110 and the memory device 120 may be provided only as an example, example embodiments are not limited thereto. For example, the controller 110 may transmit a command and an address to the memory device 120 through individual signal lines and may exchange data with the memory device 120 through individual signal lines.

In an example embodiment, the memory device 120 may include a memory circuit 121. The memory circuit 121 may include (i.e., store) device information DINF. The device information DINF may include various information required for the memory device 120 to operate. The memory device 120 may perform various operations (e.g., a read operation, a program operation, and an erase operation) based on the device information DINF stored in the memory circuit 121.

In an example embodiment, the device information DINF may include information about various operation parameters of the memory device 120, such as a read voltage level, a program voltage level, and an erase voltage level. Alternatively, the device information DINF may include various information of the memory device 120, such as an operating characteristic, a capacity, and an operating frequency. Alternatively, the device information DINF may include a variety of information of the memory device 120, such as a vendor identifier, a device model, and an operating characteristic supported by a device. However, example embodiments are not limited thereto. For example, the device information DINF may include various other information necessary for the memory device 120 to operate.

In an example embodiment, the memory circuit 121 may include a plurality of latch circuits. The plurality of latch circuits may be configured to store the device information DINF based on an electronic fuse (eFuse) manner. The device information DINF stored in the plurality of latch circuits may include an error caused by various factors. For example, neutrons may be introduced into the memory device 120 or the memory circuit 121 due to various environments, thereby causing the bit flip in the plurality of latch circuits of the memory circuit 121. The bit flip causes an error of the device information DINF stored in the memory circuit 121. This error is called a soft error. In an example embodiment, because the soft error is not a hardware defect, when a refresh or an eFuse refresh operation on the memory circuit 121 is performed, the soft error may be cured.

When the soft error occurs in the memory circuit 121, the memory device 120 may not operate normally. In an example embodiment, when the soft error occurs in information associated with a verify voltage from among the device information DINF stored in the memory circuit 121, the program operation of the memory device 120 may be performed normally (i.e., may be passed), but the data actually stored through the program operation may be different from intended data (or data provided from the outside). In this case, normal data may not be read through a subsequent read operation of the memory device 120.

According to an example embodiment, the soft error of the device information DINF stored in the memory circuit 121 may be detected by comparing various parameters during the program operation of the memory device 120. In this case, because the soft error of the device information DINF stored in the memory circuit 121 is detected in advance, the error may be corrected and the reliability of the memory device 120 may be improved. The operation of the memory device 120 according to an example embodiment will be described in detail with reference to the following drawings.

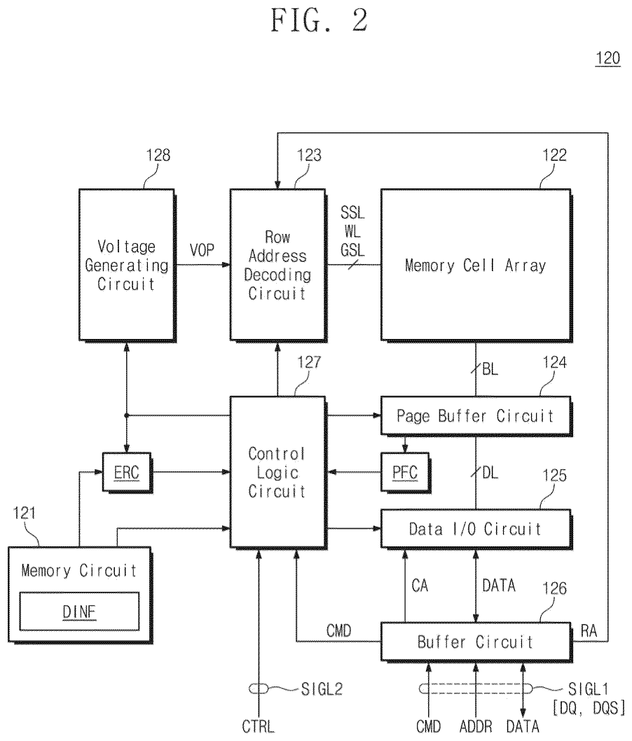

FIG. 2 is a block diagram illustrating a memory device of FIG. 1. Referring to FIGS. 1 and 2, the memory device 120 may include the memory circuit 121, a memory cell array 122, a row address decoding circuit 123, a page buffer circuit 124, a data input/output circuit 125, a buffer circuit 126, a control logic circuit 127, a voltage generating circuit 128, a pass/fail checker circuit PFC, and an error checker circuit ERC.

The memory circuit 121 may be configured to store the device information DINF. For example, the memory circuit 121 may include a plurality of latches. The plurality of latches may be configured to store the device information DINF. The device information DINF may include various information necessary for the memory device 120 to operate, which is described above. Thus, additional description will be omitted to avoid redundancy.

The memory cell array 122 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL.

The row address decoding circuit 123 may be connected to the memory cell array 122 through the string selection lines SSL, the word lines WL, and the ground selection lines GSL. The row address decoding circuit 122 may operate under control of the control logic circuit 127. For example, under control of the control logic circuit 127, the row address decoding circuit 123 may decode a row address RA received from the buffer circuit 126; based on a decoding result, the row address decoding circuit 123 may control or drive the string selection lines SSL, the word lines WL, and the ground selection lines GSL or may control voltages applied to the string selection lines SSL, the word lines WL, and the ground selection lines GSL.

The page buffer circuit 124 may be connected to the memory cell array 122 through the bit lines BL. The page buffer circuit 124 may be connected to the data input/output circuit 124 through a plurality of data lines DL. The page buffer circuit 124 may operate under control of the control logic circuit 127. For example, in the program operation of the memory device 120, the page buffer circuit 124 may store data to be programmed in the memory cell array 122 under control of the control logic circuit 127. The page buffer circuit 124 may control voltages of the bit lines BL based on the stored data and a program verify result. In the read operation of the memory device 120, the page buffer circuit 124 may sense voltages of the bit lines BL and may store the sensed voltages as read data.

The data input/output circuit 125 may be connected to the page buffer circuit 124 through the plurality of data lines DL. The data input/output circuit 126 may receive a column address CA from the buffer circuit 126. The data input/output circuit 126 may transmit the data read by the page buffer circuit 124 to the buffer circuit 126 depending on the column address CA. The data input/output circuit 125 may transmit data received from the buffer circuit 126 to the page buffer circuit 124 based on the column address CA.

The buffer circuit 126 may receive the command CMD and the address ADDR through the first signal lines SIGL1 and may exchange the data “DATA” with the controller 110 through the first signal lines SIGL1. In an example embodiment, the first signal lines SIGL1 may include signal lines through which a plurality of data signals DQ and a data strobe signal DQS are transmitted/received.

The buffer circuit 126 may operate under control of the control logic circuit 127. For example, the control logic circuit 127 may exchange the control signals CTRL with the controller 110 through the first signal lines SIGL1. The control logic circuit 127 may control the buffer circuit 126 based on the control signals CTRL such that the buffer circuit 126 routes the command CMD, the address ADDR, and the data “DATA”. Under control of the control logic circuit 127, the buffer circuit 126 may classify signals received through the first signal lines SIGL1 as the command CMD or the address ADDR. The buffer circuit 126 may transfer the command CMD to the control logic circuit 127. The buffer circuit 126 may transfer the row address RA of the address ADDR to the row decoding circuit 123 and may transfer the column address CA of the address ADDR to the data input/output circuit 125. The buffer circuit 126 may exchange the data “DATA” with the data input/output circuit 125.

The control logic circuit 127 may decode the command CMD received from the buffer circuit 126 and may control the memory device 120 or various components of the memory device 120 based on a decoding result.

Under control of the control logic circuit 127, the voltage generating circuit 128 may generate various operating voltages VOP which are used in the memory device 120. In an example embodiment, the operating voltages VOP may include various voltages such as program voltages, program verify voltages, pass voltages, selection read voltages, non-selection read voltages, and erase voltages.

In a verify read operation associated with the program operation or the erase operation of the memory device 120, the pass/fail checker circuit PFC may verify the sensing result of the page buffer circuit 124. For example, in the verify read operation which is performed in the program operation, the pass/fail checker circuit PFC may count the number of values (e.g., 0s) each corresponding to a memory cell (i.e., an on-cell) which is not programmed to a target threshold voltage or higher. The pass/fail checker circuit PFC may determine whether the program operation is passed, based on a counting result. The pass/fail checker circuit PFC may transfer pass information to the control logic circuit 127. Based on the pass information received from the pass/fail checker circuit PFC, the control logic circuit 127 may perform a subsequent program loop or may terminate the program operation.

The error checker circuit ERC may be configured to detect an error of the device information DINF stored in the memory circuit 121. For example, a plurality of verify voltages are used in the process of verifying the program operation of the memory device 120. The control logic circuit 127 may generate a plurality of verify codes corresponding to the plurality of verify voltages, based on the device information DINF stored in the memory circuit 121. The voltage generating circuit 128 may generate the plurality of verify voltages, based on the plurality of verify codes received from the control logic circuit 127.

In this case, based on a difference of (i.e., a difference between) verify codes, the error checker circuit ERC may detect whether an error occurs in the device information DINF stored in the memory circuit 121. For example, a difference corresponding to each verify voltage is included in a given range. That is, a level difference of verify codes respectively corresponding to verify voltages may also be included in a given range. When a level difference of verify codes is not included in the given range, the error checker circuit ERC may determine that an error occurs in the device information DINF stored in the memory circuit 121. The operation of the error checker circuit ERC will be described in detail with reference to the following drawings.

Below, the level difference of verify voltages or the level difference of verify codes is referred to as a “level difference (or delta)”. That is, a level difference (or delta) may indicate a difference in level of verify voltages targeted for comparison or a difference in magnitude of verify codes targeted for comparison.

In an example embodiment, information about the program pass or fail determined by the pass/fail checker circuit PFC and status information about an error detected by the error checker circuit ERC may be set as status information, and the memory device 120 may transmit the status information to the controller 110 in response to a status read command of the controller 110.

As described above, during the program operation of the memory device 120, the memory device 120 may detect an error of the device information DINF stored in the memory circuit 121, based on the level difference of verify voltages. Accordingly, an abnormal operation of the memory device 120 due to the error of the device information DINF stored in the memory circuit 121 may be prevented. The operation of the memory device 120 according to an example embodiment will be described in detail with reference to the following drawings.

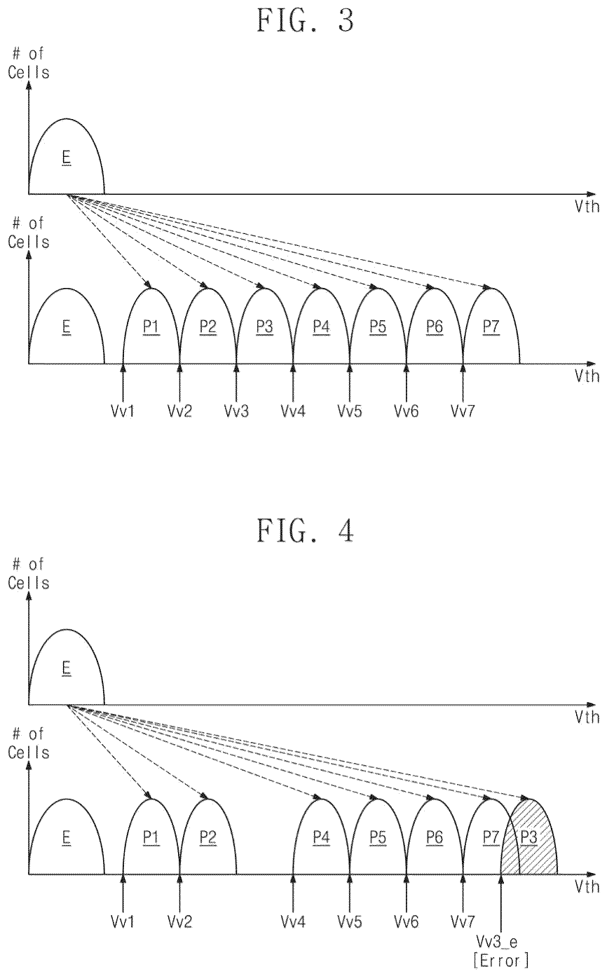

FIGS. 3 and 4 are distribution diagrams for describing a program operation of a memory device of FIG. 2. In the distribution diagrams of FIGS. 3 and 4, the horizontal axis represents a threshold voltage of a memory cell, and the vertical axis represents the number of memory cells.

Referring to FIGS. 2, 3, and 4, memory cells of the memory device 120 may initially have an erase state “E”. Through the program operation of the memory device 120, the memory cells may have one of the erase state “E” and a plurality of program states P1 to P7.

The memory device 120 may use a plurality of verify voltages Vv1 to Vv7 to verify program states of the memory cells. As an example, the memory device 120 may verify whether memory cells corresponding to the first program state P1 are normally programmed, by using the first verify voltage Vv1. For example, when a threshold voltage of a first memory cell corresponding to the first program state P1 is lower than the first verify voltage Vv1, the memory device 120 determines that the first memory cell corresponding to the first program state P1 is not yet programmed (i.e., have the erase state “E”); when the threshold voltage of the first memory cell corresponding to the first program state P1 is higher than or equal to the first verify voltage Vv1, the memory device 120 determines that the first memory cell corresponding to the first program state P1 is normally programmed.

As in the above description, the memory device 120 may verify whether memory cells corresponding to the second program state P2 are normally programmed, by using the second verify voltage Vv2; the memory device 120 may verify whether memory cells corresponding to the third program state P3 are normally programmed, by using the third verify voltage Vv3; and, the memory device 120 may verify whether memory cells corresponding to the fourth program state P4 are normally programmed, by using the fourth verify voltage Vv4. Likewise, the memory device 120 may verify whether memory cells corresponding to the fifth program state P5 are normally programmed, by using the fifth verify voltage Vv5; the memory device 120 may verify whether memory cells corresponding to the sixth program state P6 are normally programmed, by using the sixth verify voltage Vv6; and, the memory device 120 may verify whether memory cells corresponding to the seventh program state P7 are normally programmed, by using the seventh verify voltage Vv7.

As an example, the above verify operation on the program states of the memory cells may be performed by the pass/fail checker circuit PFC described with reference to FIG. 2.

In an example embodiment, the plurality of verify voltages Vv1 to Vv7 may be generated based the device information DINF stored in the memory circuit 121. For example, as described above, the control logic circuit 127 of the memory device 120 may generate the plurality of verify codes, based on the device information DINF stored in the memory circuit 121, and the voltage generating circuit 128 may generate the plurality of verify voltages Vv1 to Vv7, respectively, based on the plurality of verify codes.

When an error occurs in the device information DINF stored in the memory circuit 121, the plurality of verify codes may be changed; in this case, the plurality of verify voltages Vv1 to Vv7 may not be normally generated. This may mean that the memory cells are not normally programmed.

For example, as illustrated in FIG. 4, the third verify voltage Vv3 may be changed to a third error verify voltage Vv3_e by the error caused in the device information DINF of the memory circuit 121. Because memory cells corresponding to the third program state P3 are verified by using the third error verify voltage Vv3_e, threshold voltages of the memory cells corresponding to the third program state P3 may be higher than the third error verify voltage Vv3_e. In this case, the program operation of the memory device 120 is determined as “program pass”. However, during the read operation of the memory device 120, the memory cells corresponding to the third program state P3 may be determined as being in the seventh program state P7. That is, the read operation of the memory device 120 may not be normally performed.

According to an example embodiment, the memory device 120 may detect an error of the device information DINF stored in the memory circuit 121, based on level differences of the plurality of verify voltages Vv1 to Vv7 (or level differences of the plurality of verify codes). For example, each of a level difference of the first and second verify voltages Vv1 and Vv2, a level difference of the second and third verify voltages Vv2 and Vv3, a level difference of the third and fourth verify voltages Vv3 and Vv4, a level difference of the fourth and fifth verify voltages Vv4 and Vv5, a level difference of the fifth and sixth verify voltages Vv5 and Vv6, and a level difference of the sixth and seventh verify voltages Vv6 and Vv7 may be included in a given range. That is, the first to seventh verify voltages Vv1 to Vv7 may have a given interval. When a specific verify voltage is changed by various factors (e.g., an error of the device information DINF of the memory circuit 121) (e.g., as illustrated in FIG. 4, when the third verify voltage Vv3 is changed to the third error verify voltage Vv3_e), a level difference of verify voltages or an interval between verify voltages may be out of the given range or the given interval. In this case, the error checker circuit ERC of the memory device 120 may detect that an error occurs in the device information DINF of the memory circuit 121.

The controller 110 may receive status information about an error from the memory device 120 through the status read operation and may recognize that an error occurs in the device information DINF of the memory circuit 121, based on the received status information about the error. In this case, the controller 110 may control a refresh operation to be performed on the memory circuit 121 of the memory device 120 to cure the error of the device information DINF, and may again perform the program operation of the memory device 120. Accordingly, the issue described with reference to FIG. 4 may be solved.

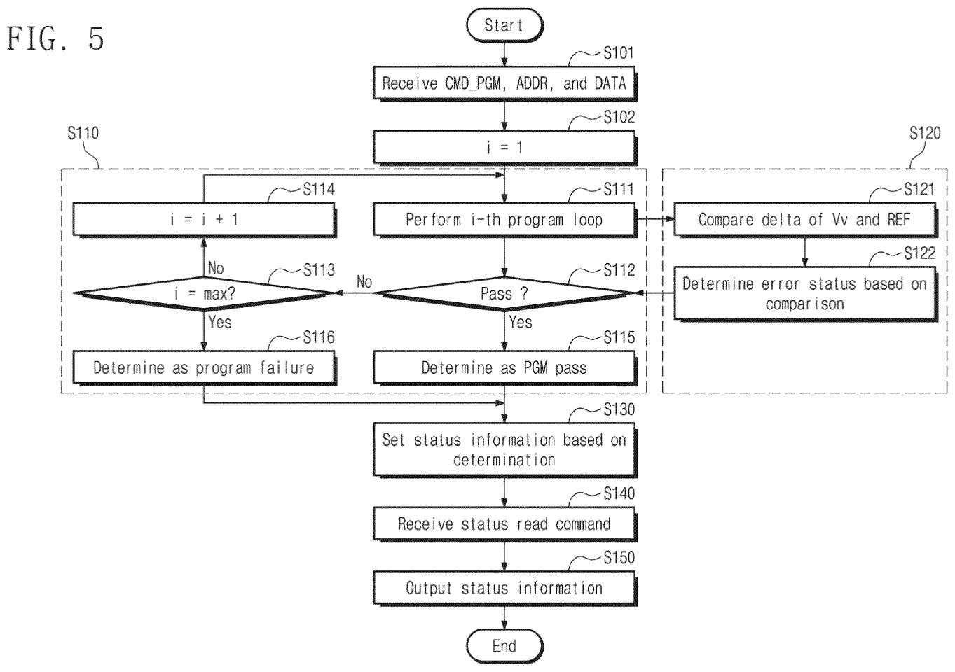

FIG. 5 is a flowchart illustrating an operation of a memory device of FIG. 2. Referring to FIGS. 2 and 5, in operation S101, the memory device 120 may receive a program command CMD_PGM, the address ADDR, and the data “DATA” from the controller 110.

In operation S102, a variable “i” is set to 1. In an example embodiment, the memory device 120 may perform the program operation based on an incremental step pulse programming (ISPP) manner. The variable “i” may be only for expressing program loops which are repeatedly performed in the memory device 120, and it may be understood that the variable “i” does not have any other meaning.

In operation S110, the memory device 120 may perform a plurality of program loops. Operation S110 may include operation S111 to operation S116.

In operation S111, the memory device 120 may perform the i-th program loop. For example, when the variable “i” is 1, the memory device 120 may perform the first program loop. The first program loop may include a first program stage of applying a first program voltage to a word line corresponding to the address ADDR (i.e., to a selected word line), and a first verification stage of applying some of the plurality of verify voltages Vv1 to Vv7 to the selected word line.

In operation S112, the memory device 120 may determine whether the program operation is passed. For example, the memory device 120 may determine whether selected memory cells connected to the selected word line are normally programmed, based on a verify result of the first verification stage.

When the selected memory cells are normally programmed, in operation S115, the memory device 120 may determine that the program operation is passed.

When the selected memory cells are not normally programmed, in operation S113, the memory device 120 may determine whether the variable “i” reaches a maximum value. When the variable “i” does not reach the maximum value (i.e., when program loops not performed exist), in operation S114, the variable “i” is increased by “1”. Afterwards, the memory device 120 may again perform operation S111.

When the variable “i” reaches the maximum value (i.e., when all the program loops have been performed), in operation S116, the memory device 120 determines that the program operation is failed.

As described above, through operation S110, the memory device 120 may program the data “DATA” in the selected memory cells connected to the selected word line corresponding to the address ADDR in response to the program command CMD_PGM.

In operation S120, the memory device 120 may detect an error status of the device information DINF stored in the memory circuit 121, based on a level difference of verify voltages. Operation S120 may include operation S121 and operation S122.

In operation S121, the memory device 120 may compare the level difference of verify voltages and a reference range REF. For example, in operation S111, the memory device 120 may perform the i-th verification stage by using some of the plurality of verify voltages Vv1 to Vv7. For convenience of description, it is assumed that the memory device 120 uses the second and third verify voltages Vv2 and Vv3 in the i-th verification stage. In this case, the control logic circuit 127 of the memory device 120 may generate second and third verify codes respectively corresponding to the second and third verify voltages Vv2 and Vv3, based on the device information DINF of the memory circuit 121. The error checker circuit ERC of the memory device 120 may identify a level difference of the second and third verify codes. The level difference of the second and third verify codes may correspond to the level difference of the second and third verify voltages Vv2 and Vv3 used by the memory device 120. The error checker circuit ERC of the memory device 120 may compare the level difference of the second and third verify codes and the reference range REF.

In operation S122, the memory device 120 may determine an error status, based on a comparison result. For example, when the level difference of the second and third verify codes is included in the reference range REF, the device information DINF used to generate the second and third verify codes may be normal (i.e., may be error-free). In contrast, when the level difference of the second and third verify codes is not included in the reference range REF, the device information DINF used to generate the second and third verify codes may include an error. In this case, the memory device 120 may determine that the device information DINF of the memory circuit 121 is in an error status (i.e., may be in a state of including an error).

In an example embodiment, the memory device 120 may perform operation S120 while operation S110 is performed, or operation S110 and operation S120 may be performed at different times. For example, the memory device 120 may perform operation S110 and operation S120 in parallel or at the same time. For example, while the memory device 120 performs the i-th program loop (or the i-th verification stage of the i-th program loop) in operation S111, the memory device 120 may perform operation S121 and operation S122 (e.g., may perform operations of generating a level difference of verify voltages used in the i-th program loop, comparing the generated level difference and a reference range, and detecting an error status based on a comparison result). That is, the memory device 120 may compare a level difference of verify voltages used in each of a plurality of program loops with the reference range REF and may determine an error status, based on a comparison result.

Afterwards, in operation S130, the memory device 120 may set status information, based on a determination result. For example, the memory device 120 may determine the pass or failure of the program operation through operation S110. Through operation S120, the memory device 120 may determine an error status of the device information DINF stored in the memory circuit 121. The control logic circuit 127 of the memory device 120 may set information about the pass or failure of the program operation and information about the error status as status information, and may store the status information in the memory circuit 121.

In operation S140, the memory device 120 may receive the status read command from the controller 110. For example, while operation S110 and operation S120 are performed, the memory device 120 may set a ready/busy signal to a busy state. After operation S110 and operation S120 are completed, the memory device 120 may set the ready/busy signal to a ready state. To check a result of the program operation of the memory device 120, the controller 110 may transmit the status read command to the memory device 120 in response to the ready/busy signal indicating the ready state.

In operation S150, the memory device 120 may transmit the status information to the controller 110 in response to the status read command. In an example embodiment, the status information transmitted to the controller 110 may include first information about the program pass or failure and second information about the error status of the device information DINF stored in the memory circuit 121. In an example embodiment, the first information may be transmitted to the controller 110 through a first data signal among the plurality of data signals DQ, and the second information may be transmitted to the controller 110 through a second data signal among the plurality of data signals DQ.

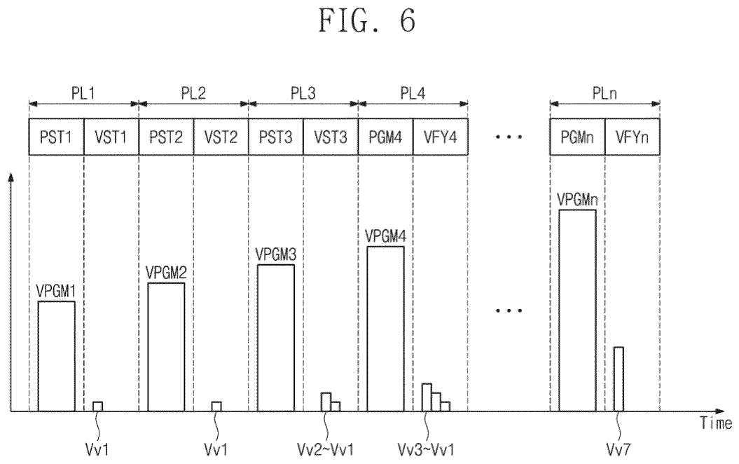

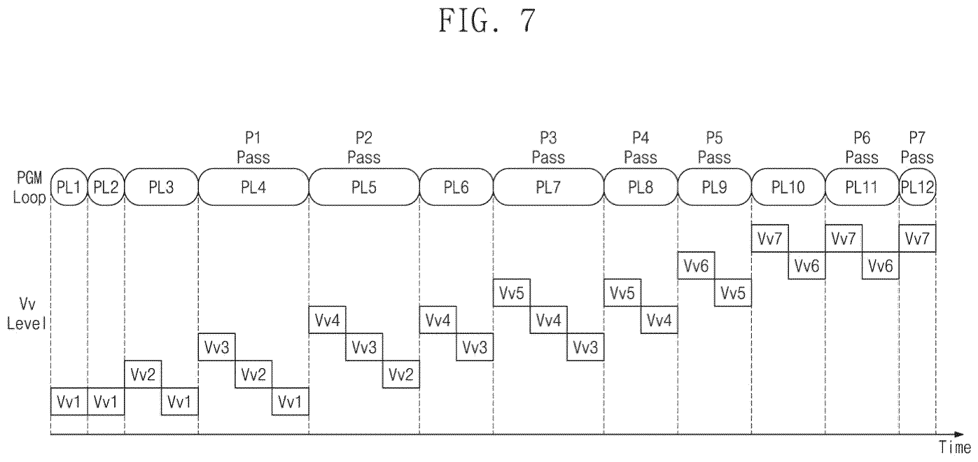

FIG. 6 is a diagram for describing operation S110 (e.g., a plurality of program loops) of FIG. 5. FIG. 7 is a diagram for describing verify voltages used in each of a plurality of program loops. A plurality of program loops and a plurality of verify voltages illustrated in FIGS. 6 and 7 are only for describing an example embodiment, and example embodiments are not limited thereto.

Referring to FIGS. 2, 5, and 6, the memory device 120 may sequentially perform a plurality of program loops PL1 to PLn. The plurality of program loops PL1 to PLn may respectively include a plurality of program stages PST1 to PSTn and may respectively include a plurality of verification stages VST1 to VSTn.

For example, the first program loop PL1 may include the first program stage PST1 and the first verification stage VST1. In the first program stage PST1, the memory device 120 may apply a first program voltage VPGM1 to a selected word line. Afterwards, in the first verification stage VST1, the memory device 120 may apply the first verify voltage Vv1 to the selected word line and may verify first memory cells corresponding to the first program state P1.

The second program loop PL2 may include the second program stage PST2 and the second verification stage VST2. In the second program stage PST2, the memory device 120 may apply a second program voltage VPGM2 to the selected word line. In this case, the second program voltage VPGM2 may be higher than the first program voltage VPGM1 as much as a given level. Afterwards, in the second verification stage VST2, the memory device 120 may apply the first verify voltage Vv1 to the selected word line and may verify the first memory cells corresponding to the first program state P1.

The third program loop PL3 may include the third program stage PST3 and the third verification stage VST3. In the third program stage PST3, the memory device 120 may apply a third program voltage VPGM3 to the selected word line. In this case, the third program voltage VPGM3 may be higher than the second program voltage VPGM2 as much as the given level. Afterwards, in the third verification stage VST3, the memory device 120 may sequentially apply the second and first verify voltages Vv2 and Vv1 to the selected word line and may verify second memory cells corresponding to the second program state P2 and the first memory cells corresponding to the first program state P1.

The fourth program loop PL4 may include the fourth program stage PST4 and the fourth verification stage VST4. In the fourth program stage PST4, the memory device 120 may apply a fourth program voltage VPGM4 to the selected word line. In this case, the fourth program voltage VPGM4 may be higher than the third program voltage VPGM3 as much as the given level. Afterwards, in the fourth verification stage VST4, the memory device 120 may sequentially apply third, second, and first verify voltages Vv3, Vv2, and Vv1 to the selected word line and may verify third memory cells corresponding to the third program state P3, the second memory cells corresponding to the second program state P2, and the first memory cells corresponding to the first program state P1.

Likewise, the n-th program loop PLn may include the n-th program stage PSTn and the n-th verification stage VSTn. In the n-th program loop PLn, the memory device 120 may apply an n-th program voltage PGMn to the selected word line. Afterwards, in the n-th verification stage VSTn, the memory device 120 may apply the seventh verify voltage Vv7 to the selected word line and may verify seventh memory cells corresponding to the seventh program state P7.

As described above, the numbers of verify voltages used in respective program loops and levels of verify voltages used in respective program loops may be different from each other. For example, as illustrated in FIG. 7, the memory device 120 may perform first to twelfth program loops PL1 to PL12. In this case, the memory device 120 may use the first verify voltage Vv1 in the first program loop PL1, may use the first verify voltage Vv1 in the second program loop PL2, may use the second and first verify voltages Vv2 and Vv1 in the third program loop PL3, may use the third, second, and first verify voltages Vv3, Vv2, and Vv1 in the fourth program loop PL4, may use the fourth, third, and second verify voltages Vv4, Vv3, and Vv2 in the fifth program loop PL5, may use the fourth and third verify voltages Vv4 and Vv3 in the sixth program loop PL6, may use the fifth, fourth, and third verify voltages Vv5, Vv4, and Vv3 in the seventh program loop PL7, may use the fifth and fourth verify voltages Vv5 and Vv4 in the eighth program loop PL8, may use the sixth and fifth verify voltages Vv6 and Vv5 in the ninth program loop PL9, may use the seventh and sixth verify voltages Vv7 and Vv6 in the tenth program loop PL10, may use the seventh and sixth verify voltages Vv7 and Vv6 in the eleventh program loop PL11, and may use the seventh verify voltage Vv7 in the twelfth program loop PL12.

In the fourth program loop PL4, programming for the first program state P1 may be passed; in the fifth program loop PL5, programming for the second program state P2 may be passed; in the seventh program loop PL7, programming for the third program state P3 may be passed; in the eighth program loop PL8, programming for the fourth program state P4 may be passed; in the ninth program loop PL9, programming for the fifth program state P5 may be passed; in the eleventh program loop PL11, programming for the sixth program state P6 may be passed; and, in the twelfth program loop PL12, programming for the seventh program state P7 may be passed.

In an example embodiment, the number and levels of verify voltages used in each program loop may be determined based on a given order or based on a verify result of memory cells in each program loop.

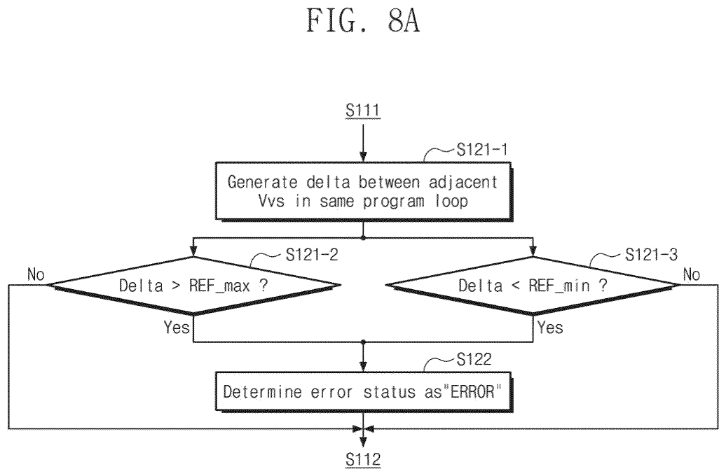

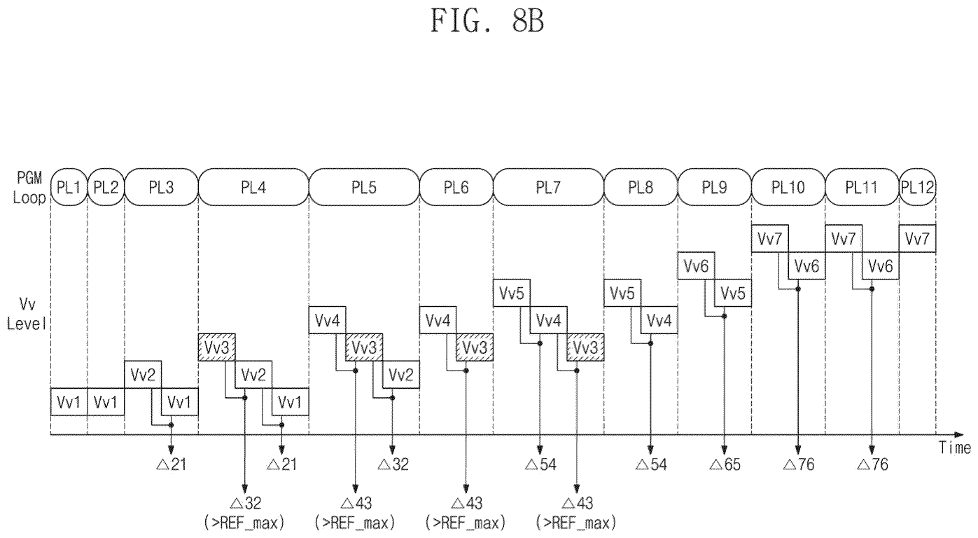

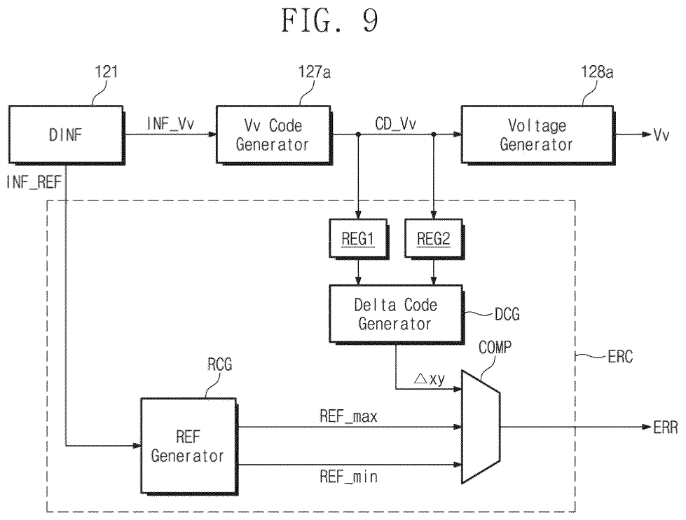

FIG. 8A is a flowchart illustrating operation S120 of FIG. 5. FIG. 8B is a diagram for describing an operation according to the flowchart of FIG. 8A. Below, for convenience of description, it is assumed that the memory device 120 performs the program operation through the first to twelfth program loops PL1 to PL12 and verify voltages used in the first to twelfth program loops PL1 to PL12 are similar to those described with reference to FIG. 7. Also, to describe an example embodiment, it is assumed that the third verify voltage Vv3 is changed due to an error of the device information DINF of the memory circuit 121.

Below, the expression “xy-th level difference Δxy” is used. The xy-th level difference Δxy indicates a level difference of the x-th verify voltage Vvx and the y-th verify voltage Vvy (i.e., Vvx-Vvy).

Referring to FIGS. 2, 5, 8A, and 8B, in operation S121-1, the memory device 120 may identify a level difference of adjacent verify voltages used in the same program loop. For example, as illustrated in FIG. 8B, the memory device 120 may sequentially perform the first to twelfth program loops PL1 to PL12. The first to seventh verify voltages Vv1 to Vv7 used in the first to twelfth program loops PL1 to PL12 are described above, and thus, additional description will be omitted to avoid redundancy.

In each of the first and second program loops PL1 and PL2, the first verify voltage Vv1 may be used; in this case, because there are no adjacent verify voltages, a level difference of verify voltages may not be generated. In the third program loop PL3, the second and first verify voltages Vv2 and Vv1 are used. In this case, the error checker circuit ERC of the memory device 120 may calculate a 21-th level difference Δ21 of the second and first verify voltages Vv2 and Vv1.

Afterwards, in the fourth program loop PL4, the third, second, and first verify voltages Vv3, Vv2, and Vv1 may be used; in this case, the error checker circuit ERC of the memory device 120 may calculate a 32-th level difference Δ32 of the third and second verify voltages Vv3 and Vv2 and the 21-th level difference Δ21 of the second and first verify voltages Vv2 and Vv1.

Likewise, in the fifth to twelfth program loops PL5 and PL12, the memory device 120 may generate a plurality of level differences Δ43, Δ32, Δ43, Δ54, Δ43, Δ54, Δ65, Δ76, and Δ76.

In operation S121-2, the memory device 120 may determine whether the generated level difference is greater than a maximum value REF_max of the reference range (for convenience of description, hereinafter referred to as a “maximum reference value”). In operation S121-3, the memory device 120 may determine whether the generated level difference is smaller than a minimum value REF_min of the reference range (for convenience of description, hereinafter referred to as a “minimum reference value”). For example, the error checker circuit ERC of the memory device 120 may determine whether the generated level difference is included the reference range REF (i.e., between the maximum reference value REF_max and the minimum reference value REF_min).

When the generated level difference is included the reference range REF (i.e., between the maximum reference value REF_max and the minimum reference value REF_min) (i.e., No in operation S121-2 and No in operation S121-3), the memory device 120 may not set an error status.

When the generated level difference is not included, or is outside, the reference range REF (i.e., not between the maximum reference value REF_max and the minimum reference value REF_min) (i.e., Yes in operation S121-2 and Yes in operation S121-3), the memory device 120 may set an error status as “ERROR”. That is, the error status may be set as the device information DINF of the memory circuit 121 includes an error.

For example, as illustrated in FIG. 8B, in the second program loop PL2, the error checker circuit ERC of the memory device 120 may generate the 21-th level difference Δ21. In this case, the 21-th level difference Δ21 may be included in the reference range REF, and thus, the error checker circuit ERC may not set the error status.

In contrast, in the fourth program loop PL4, the error checker circuit ERC of the memory device 120 may generate the 32-th level difference Δ32 and the 21-th level difference Δ21. As described above, the third verify voltage Vv3 may be changed to the third error verify voltage Vv3_e due to the error of the device information DINF. In this case, the 32-th level difference Δ32 may be greater than the maximum reference value REF_max. The error checker circuit ERC of the memory device 120 may determine the 32-th level difference Δ32 is outside of the reference range REF, and accordingly set the error status.

As described above, at least one of a plurality of verify voltages may be changed due to an error of the device information DINF stored in the memory circuit 121. In this case, even though the program state is determined by the pass/fail checker circuit PFC to be passed, normal data may not be read during a subsequent read operation. In contrast, the memory device 120 according to an example embodiment may compare a level difference of adjacent verify voltages and a reference range in each of the plurality of program loops PL1 to PL12. When at least one of a plurality of verify voltages is changed due to an error of the device information DINF stored in the memory circuit 121, the level difference of the verify voltages may be out of the reference range. In this case, the memory device 120 may set the error status, and the controller 110 may perform the refresh operation on the memory circuit 121, based on the error status of the memory device 120.

FIG. 9 is a block diagram for describing a configuration of an error checker circuit of FIG. 2. For convenience of description, components which are unnecessary to describe a configuration of the error checker circuit ERC will be omitted.

Referring to FIGS. 2 and 9, the control logic circuit 127 may include a verify code generator (i.e., verify code generator circuit) 127a. The verify code generator 127a may generate a plurality of verify codes CD_Vv1 to CD_Vv7, based on the device information DINF stored in the memory circuit 121. For example, the device information DINF may include verify voltage information INF_Vv necessary to generate the plurality of verify voltages Vv1 to Vv7. As an example, the verify voltage information INF_Vv may include information or a code associated with a default level, an offset level, etc., for each of the plurality of verify voltages Vv1 to Vv7. The verify code generator 127a may generate the plurality of verify codes CD_Vv1 to CD_Vv7 for the plurality of verify voltages Vv1 to Vv7, based on the verify voltage information INF_Vv.

A voltage generator 128a, which may be provided in the voltage generating circuit 128, may generate the plurality of verify voltages Vv1 to Vv7, based on the plurality of verify codes CD_Vv1 to CD_Vv7. For example, the plurality of verify codes CD_Vv1 to CD_Vv7 may respectively indicate values of levels of the plurality of verify voltages Vv1 to Vv7. The voltage generator 128a may generate the plurality of verify voltages Vv1 to Vv7 with levels corresponding to the plurality of verify codes CD_Vv1 to CD_Vv7.

In an example embodiment, the plurality of verify codes CD_Vv1 to CD_Vv7 may be generated only in association with a verify voltage(s) which is used in each of a plurality of program loops. For example, the verify code generator 127a may generate the first verify code CD_Vv1 based on the device information DINF in the first program loop PL1, may generate the first verify code CD_Vv1 based on the device information DINF in the second program loop PL2, and may generate the second and first verify codes CD_Vv2 and CD_Vv1 based on the device information DINF in the third program loop PL3.

The error checker circuit ERC may compare a level difference of verify codes generated by the verify code generator 127a with the reference range and may set an error status ERR based on a comparison result. The error checker circuit ERC may include a first register REG1, a second register REG2, a delta code generator (i.e., a delta code generator circuit) DCG, a reference range generator (i.e., a reference range generator circuit) RCG, and a comparator (i.e., a comparator circuit) COMP.

The first and second registers REG1 and REG2 may be configured to store a verify code generated from the verify code generator 127a. For example, in the third program loop PL3, the verify code generator 127a may generate the second verify code CD_Vv2 and the first verify code CD_Vv1, based on the device information DINF. In this case, the second verify code CD_Vv2 may be stored in the first register REG1, and the first verify code CD_Vv1 may be stored in the second register REG2.

The delta code generator DCG may identify a level difference Δxy of verify codes stored in the first and second registers REG1 and REG2. For example, in the third program loop PL3, the first register REG1 may store the second verify code CD_Vv2, and the second register REG2 may store the first verify code CD_Vv1. The delta code generator DCG may generate the 21-th level difference Δ21 of the second and first verify codes CD_Vv2 and CD_Vv1.

The reference range generator RCG may generate the maximum reference value REF_max and the minimum reference value REF_min, based on the device information DINF. For example, the device information DINF may include reference range information INF_REF for setting the reference range REF. The reference range generator RCG may generate the maximum reference value REF_max and the minimum reference value REF_min, based on the reference range information INF_REF.

The comparator COMP may compare the level difference Δxy of verify codes with the maximum reference value REF_max and the minimum reference value REF_min. When the level difference Δxy of verify codes is greater than the maximum reference value REF_max or is smaller than the minimum reference value REF_min, the comparator COMP may output the error status ERR.

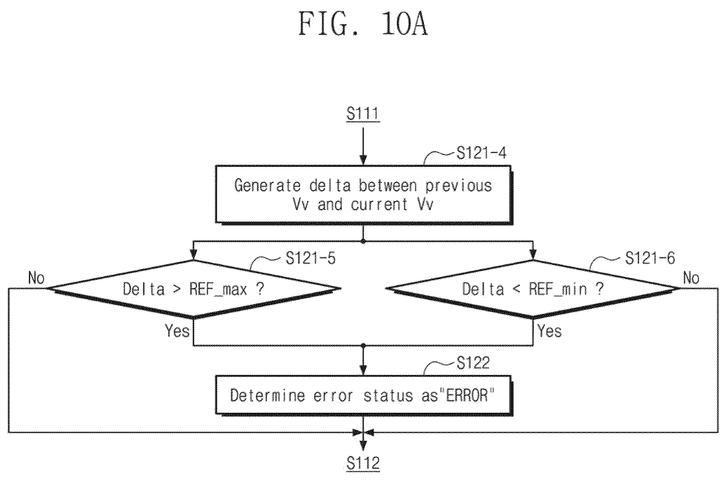

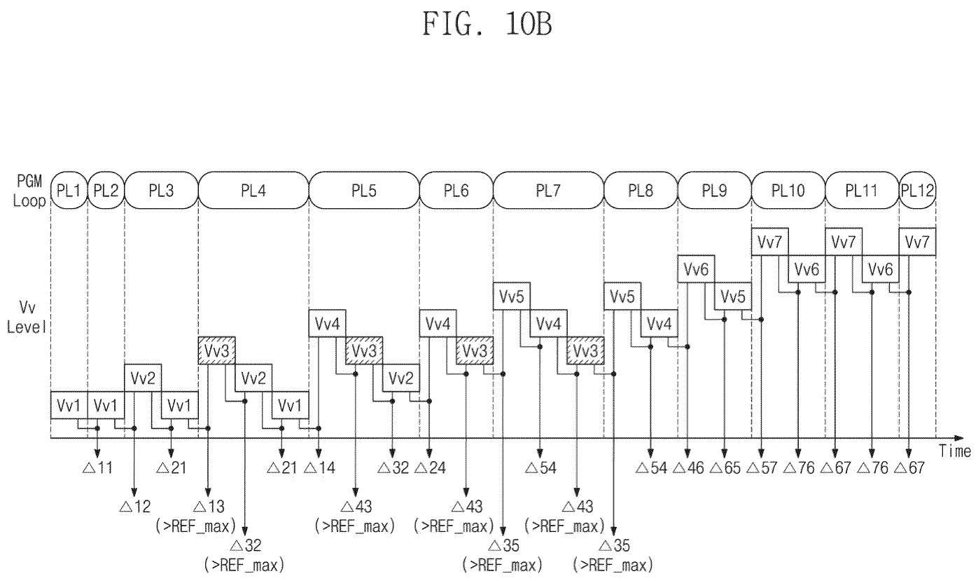

FIG. 10A is a flowchart illustrating operation S120 of FIG. 5. FIG. 10B is a diagram for describing an operation according to the flowchart of FIG. 10A. Referring to FIGS. 2, 5, 10A, and 10B, in operation S121-4, the memory device 120 may identify a level difference of a previous verify voltage and a current verify voltage. For example, as discussed with reference to FIGS. 8A and 8B, the memory device 120 may identify a level difference of adjacent verify voltages among verify voltages used in the same program loop.

In contrast, the memory device 120 shown in FIGS. 10A and 10B may identify a level difference of a previous verify voltage and a current verify voltage, regardless of a program loop. In detail, as illustrated in FIG. 10B, the memory device 120 may sequentially perform the first to twelfth program loops PL1 to PL12. The first to seventh verify voltages Vv1 to Vv7 used in the first to twelfth program loops PL1 to PL12 are described above, and thus, additional description will be omitted to avoid redundancy.

In the first program loop PL1, the first verify voltage Vv1 is used. In the second program loop PL2, the first verify voltage Vv1 is used. In the second program loop PL2, when the first verify voltage Vv1 is used, the error checker circuit ERC of the memory device 120 may generate a 11-th level difference Δ11 of the first verify voltage Vv1 being a previous verify voltage and the first verify voltage Vv1 being a current verify voltage.

In the third program loop PL3, the second and first verify voltages Vv2 and Vv1 are used. In the third program loop PL3, when the second verify voltage Vv2 is used, the error checker circuit ERC of the memory device 120 may generate a 12-th level difference Δ12 of the first verify voltage Vv1 being a previous verify voltage and the second verify voltage Vv2 being a current verify voltage. In the third program loop PL3, when the first verify voltage Vv1 is used, the error checker circuit ERC of the memory device 120 may generate a 21-th level difference Δ21 of the second verify voltage Vv2 being a previous verify voltage and the first verify voltage Vv1 being a current verify voltage.

Likewise, whenever each of the plurality of verify voltages Vv1 to Vv7 in each of the plurality of program loops PL1 to PL12 the error checker circuit ERC of the memory device 120 may identify a level difference of a previous verify voltage and a current verify voltage.

In operation S121-5, the memory device 120 may determine whether the generated level difference is greater than the maximum reference value REF_max. In operation S121-6, the memory device 120 may determine whether the generate level difference is smaller than the minimum reference value REF_min.

When the generated level difference is not greater than the maximum reference value REF_max and is not smaller than the minimum reference value REF_min, the memory device 120 may not set an error status.

When the generated level difference is greater than the maximum reference value REF_max or is smaller than the minimum reference value REF_min, the memory device 120 may set an error status.

In an example embodiment, the reference range REF (or the maximum reference value REF_max and the minimum reference value REF_min) may vary depending on a previous verify voltage and a current verify voltage. For example, when the previous verify voltage is the second verify voltage Vv2 and the current verify voltage is the first verify voltage Vv1, the 21-th level difference Δ21 may be generated, and the reference range REF may be set to a first reference range. In contrast, when the previous verify voltage is the first verify voltage Vv1 and the current verify voltage is the third verify voltage Vv3, the 13-th level difference Δ13 may be generated, and the reference range REF may be set to a second reference range. In this case, the memory circuit 121 may control an intermediate value or an average of the second reference range to be set to two times a reciprocal of an intermediate value or an average of the first reference range. For example, when the first reference range is “0.5±0.1 V”, the second reference range may be set to “−1±0.1 V”.

As described above, the memory device 120 may detect an error of the device information DINF of the memory circuit 121, based on a level difference of a previous verify voltage and a current verify voltage; in this case, the memory device 120 may detect the error of the device information DINF, which occurs during the program operation.

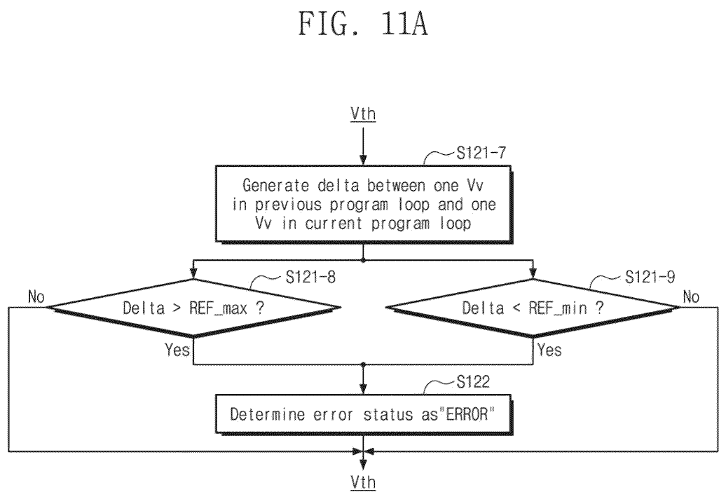

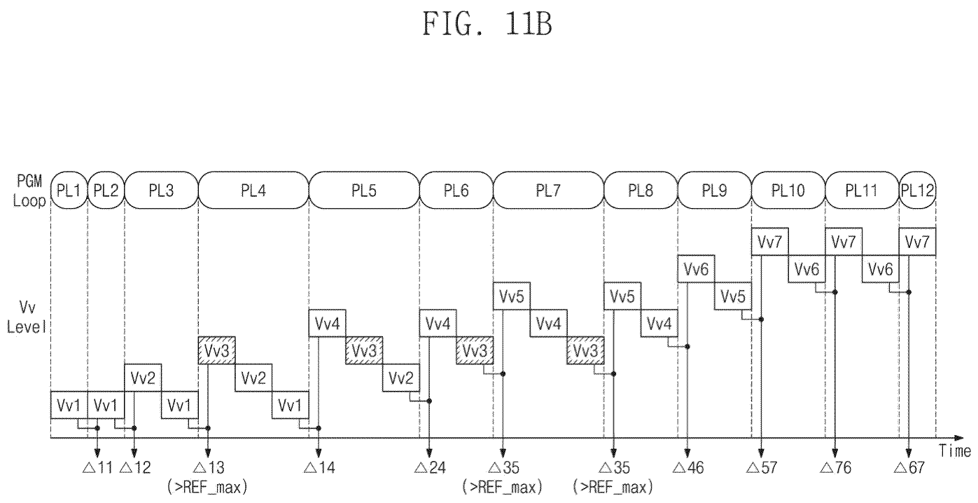

FIG. 11A is a flowchart for describing operation S120 of FIG. 5. FIG. 11B is a diagram for describing an operation according to the flowchart of FIG. 11A. Referring to FIGS. 2, 5, 11A, and 11B, in operation S121-7, the memory device 120 may identify a level difference of one of verify voltages of a previous program loop and one of verify voltages in a current program loop.

For example, as illustrated in FIG. 11B, the memory device 120 may sequentially perform the plurality of program loops PL1 to PL12. The first to seventh verify voltages Vv1 to Vv7 used in the first to twelfth program loops PL1 to PL12 are described above, and thus, additional description will be omitted to avoid redundancy.

When the memory device 120 performs the fourth program loop PL4, the error checker circuit ERC of the memory device 120 may generate a 13-th level difference Δ13 of one (e.g., the first verify voltage Vv1) among the verify voltages Vv2 and Vv1 of the third program loop PL3 being a previous program loop and one (e.g., the third verify voltage Vv3) among the verify voltages Vv3, Vv2, and Vv1 of the fourth program loop PL4 being a current program loop. Likewise, in each of the plurality of program loops PL1 to PL12, the memory device 120 may identify a level difference of one of verify voltages of a previous program loop and one of verify voltages of a current program loop.

In an example embodiment, a verify voltage, which is used to calculate a level difference, from among verify voltages of each program loop may be determined based on various manners. For example, a verify voltage which is first used in each program loop may be selected. Alternatively, a verify voltage which is last used in each program loop may be selected. Alternatively, an arbitrary verify voltage among verify voltages which are used in each program loop may be selected. The above manners are provided only as an example, and example embodiments are not limited thereto.

Returning to FIG. 11A, the memory device 120 may perform operation S121-8, operation S121-9, and operation S122. Operation S121-8, operation S121-9, and operation S122 are similar to operation S121-5, operation S121-6, and operation S122 described with reference to FIG. 10A, and thus, additional description will be omitted to avoid redundancy.

An example in which the third verify voltage Vv3 is changed due to an error of the device information DINF is described above, and level differences associated with the third verify voltage Vv3 are not included in the reference range REF. That is, an error of the device information DINF stored in the memory circuit 121 may be detected by comparing a difference in level of verify voltages with a reference range.

As described above, the memory device 120 may generate a plurality of verify voltages which are used in a plurality of program loops, based on the device information DINF stored in the memory circuit 121. In this case, when an error occurs in the device information DINF stored in the memory circuit 121, even though the program operation is passed, data may not be normally read in a subsequent read operation. According to an example embodiment, while a plurality of program loops are sequentially performed, the memory device 120 may detect an error of the device information DINF stored in the memory circuit 121, by comparing a level difference of a plurality of verify voltages Vv with the reference range. When an error of the device information DINF is detected, the memory device 120 may perform the refresh operation on the memory circuit 121 under control of the controller 110. In this case, the device information DINF may be normally recovered, and the memory device 120 may therefore normally perform the program operation.

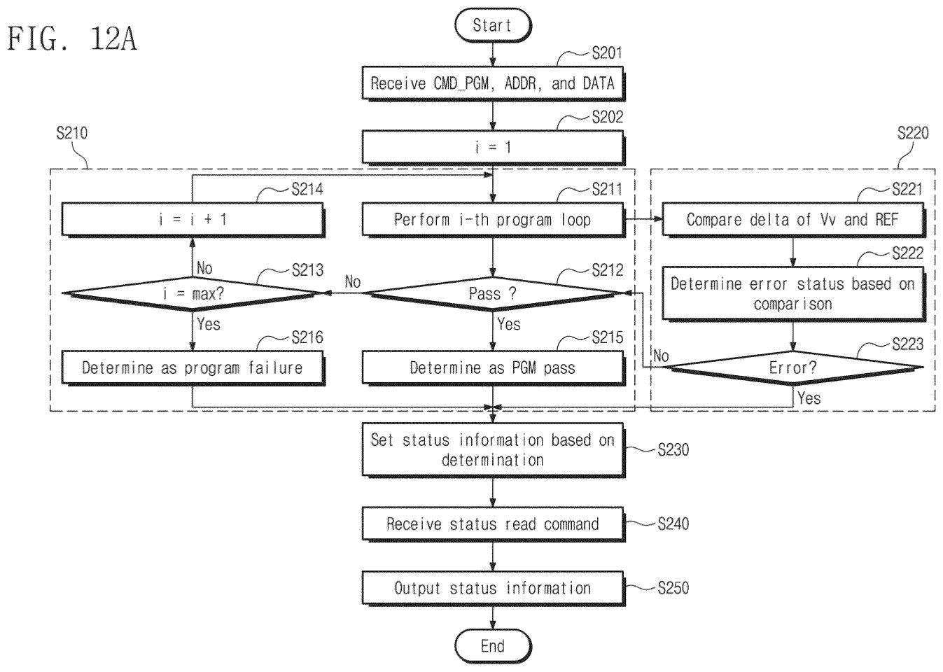

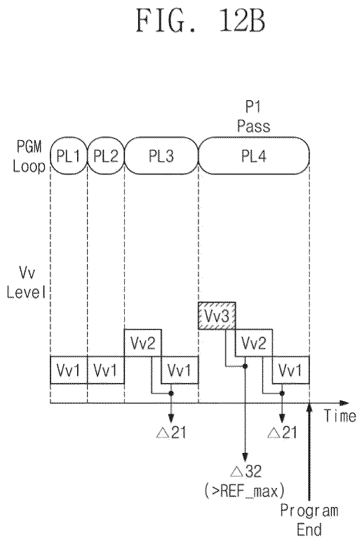

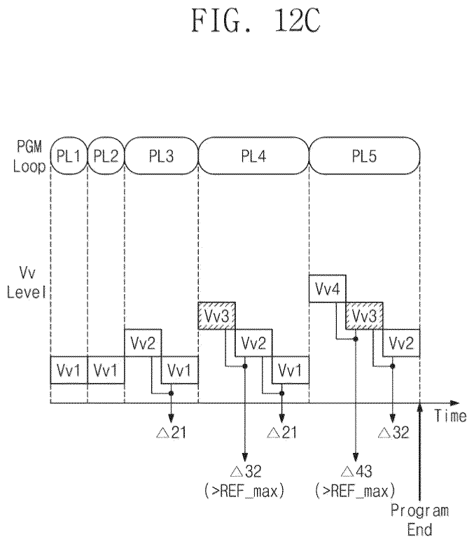

FIG. 12A is a flowchart illustrating an operation of a memory device of FIG. 2. FIGS. 12B and 12C are diagrams for describing an operation of a memory device according to the flowchart of FIG. 12A.

Referring to FIGS. 2 and 12A, the memory device 120 may perform operation S201, operation S202, operation S210, operation S220, operation S230, operation S240, and operation S250. Operation S201, operation S202, operation S210, operation S220, operation S230, operation S240, and operation S250 are similar to those described above, and thus, additional description will be omitted to avoid redundancy.

In operation S220, the memory device 120 may compare a level difference of verify voltages and the reference range REF, and may set an error status based on the comparisons. In an example embodiment, when the level difference of verify voltages is out of the reference range REF, the memory device 120 may stop the program operation. For example, operation S220 may include operation S221 to operation S223. Operation S221 and operation S222 are similar to operation S121 and operation S122 of FIG. 5, and thus, additional description will be omitted to avoid redundancy.

In operation S223, the memory device 120 may determine whether an error occurs in the device information DINF. For example, as described above, when the level difference of verify voltages is not out of the reference range REF, the error checker circuit ERC of the memory device 120 may not set the error status. In this case, the memory device 120 may perform a next program loop (e.g., may perform operation S212).

When the level difference of verify voltages is out of the reference range REF, the error checker circuit ERC of the memory device 120 may set the error status. In this case, the memory device 120 may stop a next program loop and may set status information in operation S230. That is, when that an error occurs in the device information DINF is detected by the error checker circuit ERC, the memory device 120 may stop the program loop and may set the status information. In an example embodiment, the status information may include information about the error status. In this case, because the remaining program loops are stopped and subsequent follow-up measures (e.g., a refresh operation on the memory circuit 121) are performed before the remaining program loops are performed, unnecessary operations of the memory device 120 may decrease.

For example, as illustrated in FIG. 12B, in the fourth program loop PL4, the memory device 120 may use the third, second, and first verify voltages Vv3, Vv2, and Vv1. In this case, the error checker circuit ERC of the memory device 120 may generate the 32-th level difference Δ32 and the 21-th level difference Δ21. Because the third verify voltage Vv3 is changed due to an error of the device information DINF, the 32-th level difference Δ32 may be greater than the maximum reference value REF_max. In response to that the 32-th level difference Δ32 is greater than the maximum reference value REF_max, the error checker circuit ERC may set the error status. In this case, the memory device 120 may terminate the program operation without performing a subsequent program loop. Information about the error status is included in the status information. Afterwards, in response to the status read command received from the controller 110, the memory device 120 may transmit the status information including the information about the error status to the controller 110.

Alternatively, as illustrated in FIG. 12C, the memory device 120 may perform the fourth program loop PL4. In this case, the error checker circuit ERC may operate as described with reference to FIG. 12B and may detect that the 32-th level difference Δ32 is out of the reference range REF. Afterwards, the memory device 120 may perform the fifth program loop PL5. In the fifth program loop PL5, the fourth, third, and second verify voltages Vv4, Vv3, and Vv2 may be used. In this case, the error checker circuit ERC of the memory device 120 may generate the 43-th level difference Δ43 and the 32-th level difference Δ32. Because the third verify voltage Vv3 is changed due to an error of the device information DINF, each of the 43-th level difference Δ43 and the 32-th level difference Δ32 may be greater than the maximum reference value REF_max.

That is, when the fifth program loop PL5 is performed, the error checker circuit ERC may detect the following event three times: that the level difference of verify voltages is out of the reference range REF. In this case, the memory device 120 may stop subsequent program loops, and the memory device 120 and the controller 110 may operate as described with reference to FIG. 12B. That is, as described with reference to FIG. 12C, when an error is detected by the error checker circuit ERC as much as the given (i.e., threshold) number of times (e.g., when a level difference of verify voltages is out of the reference range), the memory device 120 may stop the program operation.

FIGS. 12A to 12C are described based on a configuration where the error checker circuit ERC of the memory device 120 calculates or generates a level difference of adjacent verify voltages in the same program loop, but example embodiments are not limited thereto. The error checker circuit ERC may operate based on one of example embodiments described above or based on a combination thereof.

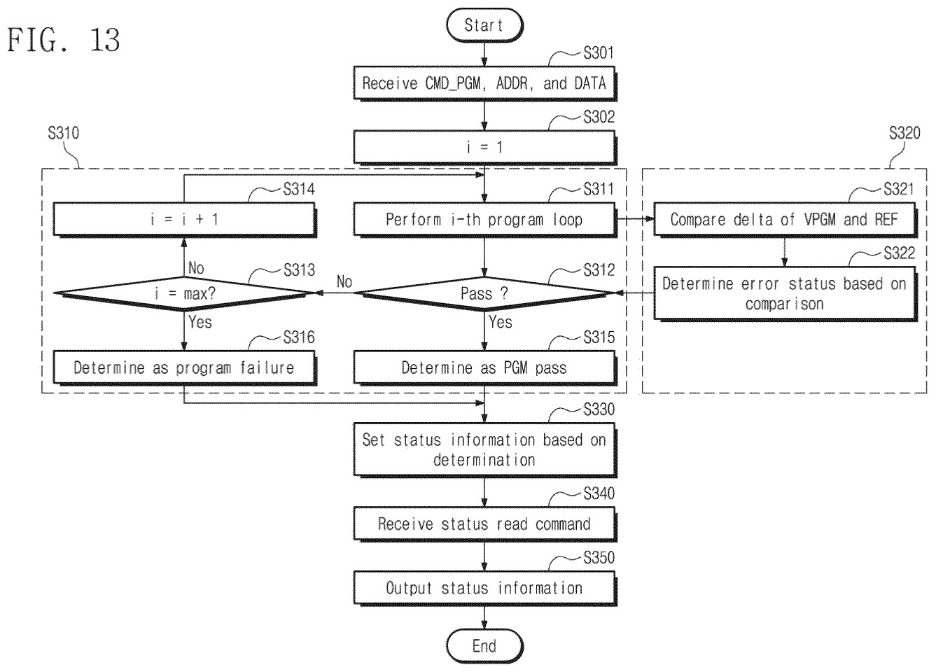

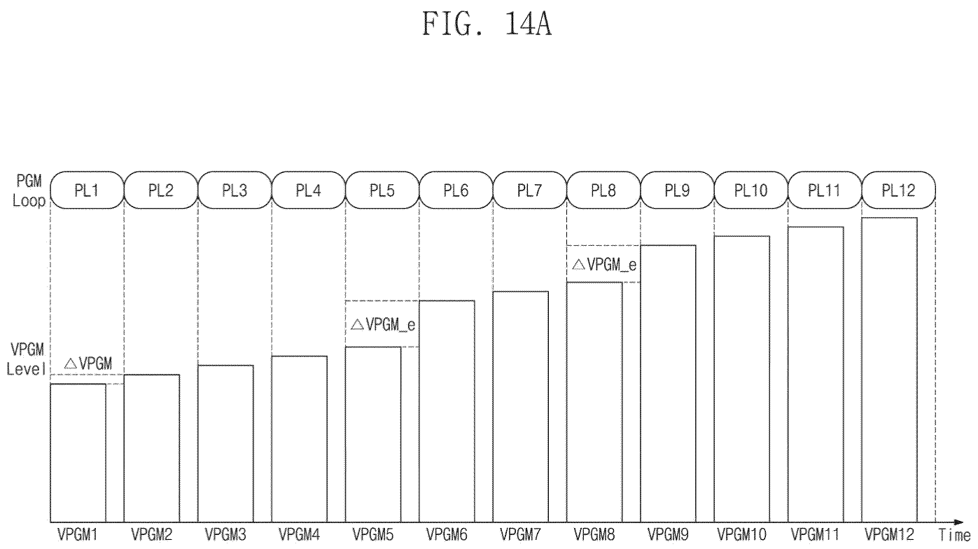

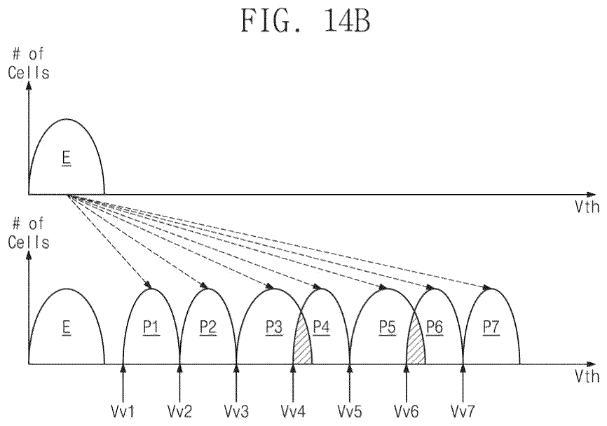

FIG. 13 is a flowchart illustrating an operation of a memory device of FIG. 2. FIGS. 14A and 14B are diagrams for describing an operation according to the flowchart of FIG. 13. Referring to FIGS. 2, 13, 14A, and 14B, the memory device 120 may perform operation S301, operation S302, operation S310, operation S320, operation S330, operation S340, and operation S350. Operation S301, operation S302, operation S310, operation S330, operation S340, and operation S350 of FIG. 13 are similar to operation S101, operation S102, operation S110, operation S130, operation S140, and operation S150 of FIG. 5, and thus, additional description will be omitted to avoid redundancy.

As discussed above, the memory device 120 may detect an error of the device information DINF of the memory circuit 121, based on a level difference of verify voltages. However, example embodiments are not limited thereto. For example, the device information DINF may include various information necessary for the memory device 120 to operate. As an example, the device information DINF may include information about a start program voltage, information about an increment of a program voltage, etc.

In operation S320, the memory device 120 may detect an error of the device information DINF, based on level differences of program voltages used in a plurality of program loops.

In operation S321, the memory device 120 may compare a level difference of program voltages and the reference range REF. For example, the memory device 120 may sequentially perform a plurality of program loops. As the plurality of program loops are sequentially performed, the program voltage may increase. In this case, the control logic circuit 127 of the memory device 120 may generate a program voltage code for a program voltage, based on the device information DINF, and the voltage generating circuit 128 may generate the program voltage, based on the program voltage code. The error checker circuit ERC may calculate a level difference of program voltages, based on the program voltage code and may determine whether the level difference of program voltages is included in the reference range REF.

In operation S322, the memory device 120 may set an error status, based on a determination result. For example, when the level difference of program voltages is included in the reference range REF, the memory device 120 may not set the error status. When the level difference of program voltages is out of the reference range REF, the memory device 120 may set the error status.

In an example embodiment, when the level difference of program voltages (that is, the increment of the program voltage) is out of the reference range REF, memory cells may not be normally programmed. For example, as illustrated in FIG. 14A, the memory device 120 may sequentially perform the first to twelfth program loops PL1 to PL12. First to twelfth program voltages VPGM1 to VPMG12 may be respectively used in the first to twelfth program loops PL1 to PL12. In an ideal case, each of the first to twelfth program voltages VPGM1 to VPMG12 may have a given level difference (or a given increment).

When an error occurs in the information about the start program voltage and the information about the program voltage increment included in the device information DINF, a level of a program voltage used in each program loop may change. For example, the start program voltage may be the first program voltage VPGM1, and the program voltage increment may be ΔVPGM. In this case, it is assumed that the increment of the fifth program voltage VPGM5 used in the fifth program loop PL5 is changed to ΔVPGM_e due to the error of the device information DINF and the increment of the ninth program voltage VPGM9 used in the ninth program loop PL9 is changed to ΔVPGM_e due to the error of the device information DINF.

In this case, as a relatively high program voltage is applied in each program loop, memory cells corresponding to some program states may be over-programmed. For example, in the fifth program loop PL5, verifying for memory cells corresponding to the second to fourth program states P2 to P4 may be performed; in this case, the memory cells corresponding to the third program state P3 may have threshold voltages higher than the fourth verify voltage Vv4 due to a relatively high program voltage. As in the above description, in the ninth program loop PL9, verifying for memory cells corresponding to the fifth and sixth program states P5 and P6 may be performed; in this case, the memory cells corresponding to the fifth program state P5 may have threshold voltages higher than the sixth verify voltage Vv6 due to a relatively high program voltage. In this case, the program operation may be determined as “pass”, but the over-programmed memory cells may cause an error in the read operation to be performed later.

Accordingly, in each program loop, the memory device 120 according to an example embodiment may detect an error of the device information DINF of the memory circuit 121, based on whether a level difference of program voltages is out of the reference range REF. In this case, through the follow-up measures, the device information DINF of the memory circuit 121 may be recovered, and thus, the memory device 120 may normally perform the program operation.

As described above, the memory device 120 may include the memory circuit 121 including the device information DINF. The device information DINF may include various information necessary for the memory device 120 to operate. When an error occurs in the device information DINF due to various factors, verify voltages or program voltages which are used in the memory device 120 may be changed; in this case, data may not be normally programmed in memory cells, but the program operation may be determined as “pass”. In this case, the data may not be normally read in a subsequent read operation, and the data may be lost.

The memory device 120 according to an example embodiment may detect an error of the device information DINF stored in the memory circuit 121, based on a level difference of verify voltages or program voltages, during the program operation. As described above, in this case, even though the program operation is determined as “pass”, because the error of the device information DINF is capable of being detected, the memory device 120 may recover the device information DINF through the follow-up measures (e.g., the refresh operation on the memory circuit 121). In this case, the memory device 120 may perform the normal program operation. Accordingly, reliability and performance of the memory device 120 are improved.

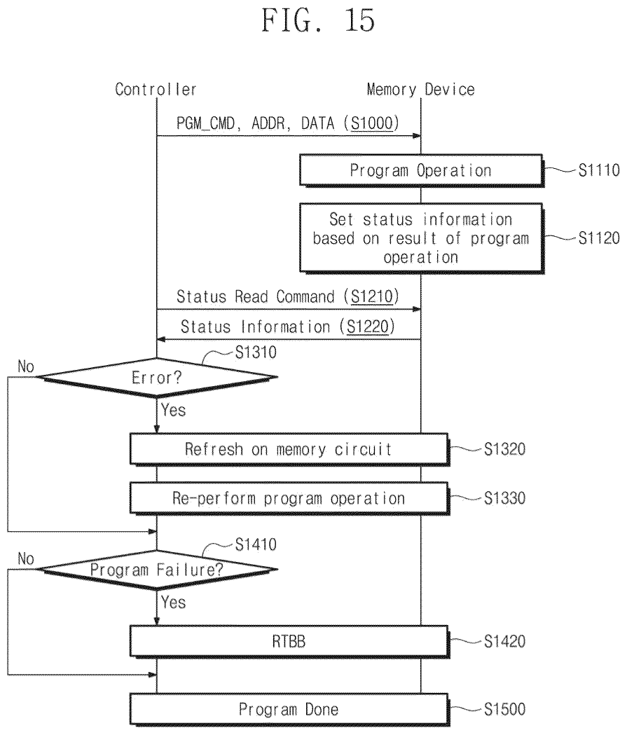

FIG. 15 is a flowchart illustrating an operation of a storage device of FIG. 1. Referring to FIGS. 1 and 15, in operation S1000, the controller 110 may transmit the program command CMD_PGM, the address ADDR, and the data “DATA” to the memory device 120.

In operation S1110, the memory device 120 may perform the program operation. For example, the memory device 120 may perform the program operation on memory cells connected to a selected word line corresponding to the address ADDR in response to the program command CMD_PGM. Through the program operation, the memory device 120 may store data in the memory cells connected to the selected word line. In an example embodiment, the memory device 120 may perform the program operation, based on at least one of the methods described with reference to FIGS. 1 to 14B or based on a combination thereof. That is, the memory device 120 may detect an error of the device information DINF, based on at least one of the methods described with reference to FIGS. 1 to 14B or based on a combination thereof.

In operation S1120, based on a result of the program operation, the memory device 120 may set first information about a program pass/failure and second information about an error status as status information.

In operation S1210, the controller 110 may transmit the status read command to the memory device 120. For example, when the memory device 120 performs the program operation, the ready/busy signal maintains the busy state. When the memory device 120 completes the program operation, the ready/busy signal is changed to the ready state. The controller 110 may transmit the status read command to the memory device 120 in response to the ready/busy signal indicating the ready state.

In operation S1220, the memory device 120 may transmit the status information to the controller 110 in response to the status read command. In an example embodiment, the status information may include the first information about pass/failure of the program operation and the second information about an error status. In an example embodiment, the first information may be transmitted through a first data signal among a plurality of data signals, and the second information may be transmitted through a second data signal among the plurality of data signals.

In operation S1310, the controller 110 may determine the error status, based on the status information. For example, the status information may include the first information about pass/failure of the program operation and the second information about an error status. The controller 110 may determine the error status (e.g., that an error occurs in the device information DINF), based on the second information.

When the second information indicates the error status (i.e., indicates that an error occurs in the device information DINF), in operation S1320, the controller 110 and the memory device 120 may perform the refresh operation on the memory circuit 121. For example, the controller 110 may perform the refresh operation on the memory circuit 121 through an information block data read (IDR) reset operation on the memory device 120. In this case, as device information DINF is newly or again stored in the memory circuit 121, the error included in the previous device information DINF may be recovered.

In operation S1320, the controller 110 and the memory device 120 may again perform the program operation.

When the second information does not indicate the error status (i.e., indicates that an error is absent from the device information DINF), in operation S1410, the controller 110 may determine whether the program operation is passed or failed.

When the first information about the status information indicates the program failure (i.e., Yes in operation S1410), in operation S1420, the controller 110 and the memory device 120 may process a memory block corresponding to the address ADDR as a runtime bad block (RTBB). Afterwards, the controller 110 may again perform the program operation on any other memory block.

When the first information about the status information indicates the program pass (i.e., No in operation S1410), in operation S1500, the program operation may be done.

The above examples are described based on the program operation of the memory device 120, but example embodiments are not limited thereto. For example, the memory device 120 may detect an error of the device information DINF through a method similar to the above method in the erase operation (e.g., by comparing a level difference of erase voltages with a reference range or comparing a level difference of erase verify voltages with a reference range). Alternatively, the memory device 120 may detect an error of the device information DINF through a method similar to the above method in the read operation (e.g., by comparing a level difference of read voltages with a reference range or comparing a level difference of non-selection read voltages with a reference range).

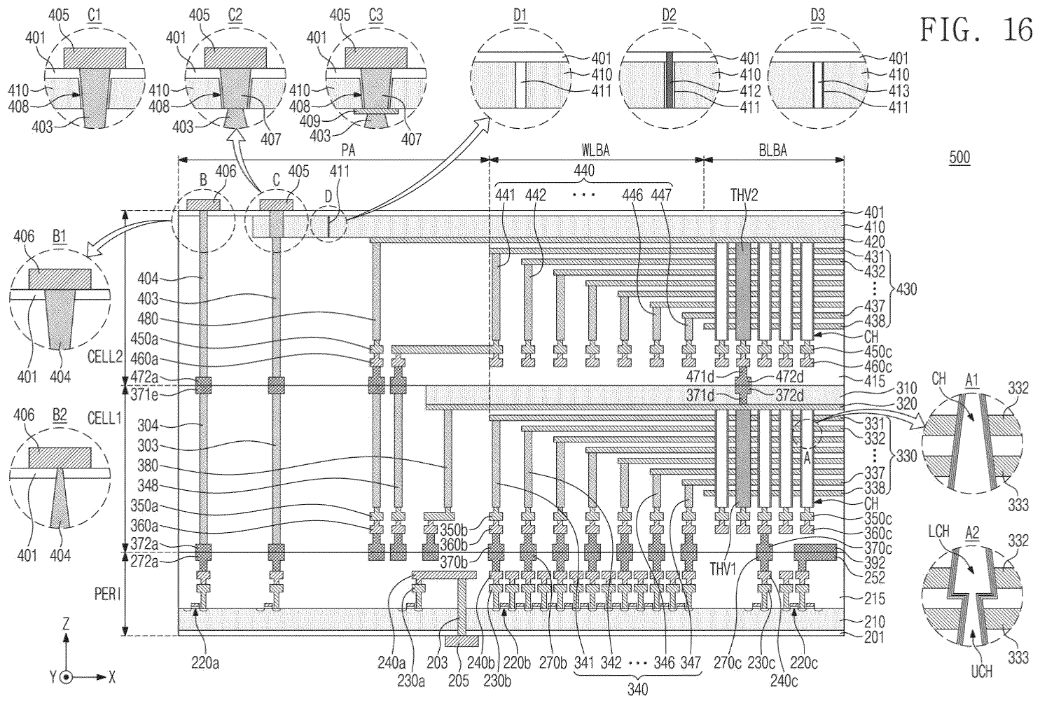

FIG. 16 is a view for describing a memory device 500 according to an example embodiment.

Referring to FIG. 16, the memory device 5000 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

The memory device 500 may include at least one upper chip including a cell region. For example, as illustrated in FIG. 16, the memory device 500 may be implemented to include two upper chips. However, this is illustrative, and the number of upper chips is not limited thereto. In the case in which the memory device 500 is implemented to include two upper chips, the memory device 500 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 16, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of aluminum At least some of the additional metal lines formed on the second metal lines 240a, 240b, and 240c may be formed of copper having a lower electrical resistivity than the aluminum of the second metal lines 240a, 240b, and 240c.

The interlayer insulating layer 115 may be disposed on the first substrate 210 and may include an insulating material, such as silicon oxide or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (the Z-axis direction) perpendicular to an upper surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked in a direction (the Z-axis direction) perpendicular to an upper surface of the third substrate 410. The second substrate 310 and the third substrate 410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In an example embodiment, as illustrated in A1, the channel structure CH may be provided in the bit line bonding region BLBA and may extend in the direction perpendicular to the upper surface of the second substrate 310 to penetrate the word lines 330, the string selection lines, and the ground selection line. The channel structure CH may include a data storage layer, a channel layer, and a buried insulating layer. The channel layer may be electrically connected with a first metal line 350c and a second metal line 360c in the bit line bonding region BLBA. For example, the second metal line 360c may be a bit line and may be connected to the channel structure CH through the first metal line 350c. The bit line 360c may extend in a first direction (a Y-axis direction) parallel to the upper surface of the second substrate 310.

In an example embodiment, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 310 and may penetrate the common source line 320 and the lower word lines 331 and 332. The lower channel LCH may include a data storage layer, a channel layer, and a buried insulating layer and may be connected with the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected with the first metal line 350c and the second metal line 360c. As the length of a channel is increased, it may be difficult to form a channel having a constant width due to process reasons. The memory device 500 according to an example embodiment may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 332 and the word line 333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

It is illustrated in A2 that the number of lower word lines 331 and 332 penetrated by the lower channel LCH is smaller than the number of upper word lines 333 to 338 penetrated by the upper channel UCH. However, this is illustrative, and example embodiments are not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 16, the first through-electrode THV1 may penetrate the common source line 320 and the plurality of word lines 330. However, this is illustrative, and the first through-electrode THV1 may additionally penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In an example embodiment, the first through-electrode THV1 and the second through-electrode THV2 may be electrically connected through a first through-metal pattern 372d and a second through-metal pattern 472d. The first through-metal pattern 372d may be formed on a lower side of the first upper chip including the first cell region CELL1, and the second through-metal pattern 472d may be formed on an upper side of the second upper chip including the second cell region CELL2. The first through-electrode THV1 may be electrically connected with the first metal line 350c and the second metal line 360c. A lower VIA 371d may be formed between the first through-electrode THV1 and the first through-metal pattern 372d, and an upper VIA 471d may be formed between the second through-electrode THV2 and the second through-metal pattern 472d. The first through-metal pattern 372d and the second through-metal pattern 472d may be connected by a bonding method.

Furthermore, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the first cell region CELL1. The upper metal pattern 392 of the first cell region CELL1 and the upper metal pattern 252 of the peripheral circuit region PERI may be electrically connected to each other by a bonding method. In the bit line bonding region BLBA, the bit line 360c may be electrically connected with a page buffer included in the peripheral circuit region PERI. For example, some of the circuit elements 220c of the peripheral circuit region PERI may provide a page buffer, and the bit line 360c may be electrically connected with the circuit elements 220c providing the page buffer through an upper bonding metal 370c of the first cell region CELL1 and an upper bonding metal 270c of the peripheral circuit region PERI.

Continuously referring to FIG. 16, in the word line bonding region WLBA, the word lines 330 of the first cell region CELL1 may extend in a second direction (an X-axis direction) parallel to the upper surface of the second substrate 310 and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the first cell region CELL1 and an upper bonding metal 270b of the peripheral circuit region PERI.

The cell contact plugs 340 may be electrically connected with a row decoder included in the peripheral circuit region PERI. For example, some of the circuit elements 220b of the peripheral circuit region PERI may provide a row decoder, and the cell contact plugs 340 may be electrically connected with the circuit elements 220b providing the row decoder through the upper bonding metal 370b of the first cell region CELL1 and the upper bonding metal 270b of the peripheral circuit region PERI. In an example embodiment, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

Likewise, in the word line bonding region WLBA, the word lines 430 of the second cell region CELL2 may extend in the second direction (the X-axis direction) parallel to the upper surface of the third substrate 410 and may be connected with a plurality of cell contact plugs 440 (441 to 447). The cell contact plugs 440 may be connected with the peripheral circuit region PERI through an upper metal pattern of the second cell region CELL2, a lower metal pattern and an upper metal pattern of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metal 370b and the upper bonding metal 270b may be formed of aluminum, copper, or tungsten.

In the external pad bonding region PA, a lower metal pattern 371e may be formed on a lower portion of the first cell region CELL1, and an upper metal pattern 472a may be formed on an upper portion of the second cell region CELL2. The lower metal pattern 371e of the first cell region CELL1 and the upper metal pattern 472a of the second cell region CELL2 may be connected by a bonding method in the external pad bonding region PA. Likewise, an upper metal pattern 372a may be formed on an upper portion of the first cell region CELL1, and an upper metal pattern 272a may be formed on an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be disposed in the external pad bonding region PA. The common source line contact plugs 380 and 480 may be formed of a conductive material, such as metal, a metal compound, or doped poly-silicon. The common source line contact plug 380 of the first cell region CELLI may be electrically connected with the common source line 320, and the common source line contact plug 480 of the second cell region CELL2 may be electrically connected with the common source line 420. A first metal line 350a and a second metal line 360a may be sequentially stacked on an upper portion of the common source line contact plug 380 of the first cell region CELL1, and a first metal line 450a and a second metal line 460a may be sequentially stacked on an upper portion of the common source line contact plug 480 of the second cell region CELL2.

Input/output pads 205, 405, and 406 may be disposed in the external pad bonding region PA. Referring to FIG. 16, a lower insulating layer 201 may cover a lower surface of the first substrate 210, and the first input/output pad 205 may be formed on the lower insulating layer 201. The first input/output pad 205 may be connected with at least one of the plurality of circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

An upper insulating layer 401 may be formed on the third substrate 410 to cover the upper surface of the third substrate 410. The second input/output pad 405 and/or the third input/output pad 406 may be disposed on the upper insulating layer 401. The second input/output pad 405 may be connected with at least one of the plurality of circuit elements 220a disposed in the peripheral circuit region PERI through second input/output contact plugs 403 and 303, and the third input/output pad 406 may be connected with at least one of the plurality of circuit elements 220a disposed in the peripheral circuit region PERI through third input/output contact plugs 404 and 304.

In an example embodiment, the third substrate 410 may not be disposed in the regions in which the input/output contact plugs are disposed. For example, as illustrated in B, the third input/output contact plug 404 may be separated from the third substrate 410 in a direction parallel to the upper surface of the third substrate 410, may penetrate an interlayer insulating layer 415 of the second cell region CELL2, and may be connected to the third input/output pad 406. In this case, the third input/output contact plug 404 may be formed through various processes.

For example, as illustrated in B1, the third input/output contact plug 404 may extend in the third direction (the Z-axis direction) and may have an increasing diameter toward the upper insulating layer 401. That is, while the channel structure CH described with reference to A1 has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in B2, the third input/output contact plug 404 may extend in the third direction (the Z-axis direction) and may have a decreasing diameter toward the upper insulating layer 401. That is, likewise to the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In an example embodiment, an input/output contact plug may be disposed to overlap the third substrate 410. For example, as illustrated in C, the second input/output contact plug 403 may be formed through the interlayer insulating layer 415 of the second cell region CELL2 in the third direction (the Z-axis direction) and may be electrically connected to the second input/output pad 405 through the third substrate 410. In this case, a connection structure of the second input/output contact plug 403 and the second input/output pad 405 may be implemented in various ways.

For example, as illustrated in C1, an opening 408 may be formed through the third substrate 410, and the second input/output contact plug 403 may be directly connected to the second input/output pad 405 through the opening 408 formed in the third substrate 410. In this case, as illustrated in C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in C2, the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in C2, the contact 407 may have an increasing diameter toward the second input/output pad 405, and the second input/output contact plug 403 may have a decreasing diameter toward the second input/output pad 405. For example, the third input/output contact plug 403 may be formed together with the cell contact plugs 440 before the second cell region CELL2 and the first cell region CELL1 are coupled by a bonding method, and the contact 407 may be formed after the second cell region CELL2 and the first cell region CELL1 are coupled by the bonding method.

For example, as illustrated in C3, a stopper 409 may be additionally formed on an upper surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Similar to the second and third input/output contact plugs 403 and 404 of the second cell region CELL2, the second and third input/output contact plugs 303 and 304 of the first cell region CELL1 may have a decreasing diameter toward the lower metal pattern 371e, or may have an increasing diameter toward the lower metal pattern 371e.

In some example embodiments, a slit 411 may be formed in the third substrate 410. For example, the slit 411 may be formed at any position in the external pad bonding region PA. For example, as illustrated in D, the slit 411 may be located between the second input/output pad 405 and the cell contact plugs 440 when viewed on a plane. However, this is illustrative, and the slit 411 may be formed such that the second input/output pad 405 is located between the slit 411 and the cell contact plugs 440 when viewed on the plane.

For example, as illustrated in D1, the slit 411 may be formed through the third substrate 410. For example, the slit 411 may be used to prevent the third substrate 410 from being finely cracked when the opening 408 is formed. However, this is illustrative, and the slit 411 may be formed to have a depth ranging from about 60% to about 70% of the thickness of the third substrate 410.

For example, as illustrated in D2, a conductive material 412 may be formed in the slit 411. For example, the conductive material 412 may be used to discharge a leakage current generated while circuit elements in the external pad bonding region PA are driven. In this case, the conductive material 412 may be connected to an external ground line.

For example, as illustrated in D3, an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be interrupted by forming the insulating material 413 in the slit 411.

In some example embodiments, the first to third input/output pads 205, 405, and 406 may be selectively formed. For example, the memory device 500 may be implemented to include only the first input/output pad 205 disposed on the first substrate 201, only the second input/output pad 405 disposed on the third substrate 410, or only the third input/output pad 406 disposed on the upper insulating layer 401.

In some example embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded to each other, and an insulating layer for covering an upper surface of the common source line 320 or a conductive layer for connection may be formed. Similarly, the third substrate 410 of the second cell region CELL2 may be removed before or after the first cell region CELL1 and the second cell region CELL2 are bonded to each other, and the upper insulating layer 401 for covering an upper surface of the common source line 420 or a conductive layer for connection may be formed.

In an example embodiment, the memory device 500 of FIG. 16 may be the memory device 120 described with reference to FIGS. 1 to 15. The memory device 500 of FIG. 16 may operate based on the operation method described with reference to FIGS. 1 to 15. The memory circuit 121 and the error checker circuit ERC described with reference to FIGS. 1 to 15 may be formed in the peripheral circuit region PERI of FIG. 16.

According to example embodiments, a memory device may compare a level difference of verify voltages and a reference range during a program operation. When the level difference of verify voltages is out of the reference range, the memory device may determine that an error occurs in device information. In this case, under control of a controller, the memory device may perform the refresh operation on a memory circuit where the device information is stored, and perform a program operation again. Thus, the error occurring in the device information may be recovered. Accordingly, a memory device with improved reliability and an operation method thereof are provided.

In some example embodiments, each of the components represented by a block as illustrated in FIGS. 1, 2 and 9 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of example embodiments have been particularly shown and described, it will be understood that various changes in form and details may be made therein without departing from the spirit and scope of the following claims.

What is claimed is:

1. A method of operating a memory device which includes a memory circuit, the method comprising:
receiving a program command, an address, and data from a controller; and
performing a program operation on a selected word line corresponding to the address according to the program command to store the data,
wherein the program operation comprises:
applying a first program voltage to the selected word line;
applying a first verify voltage and a second verify voltage to the selected word line based on device information stored in the memory circuit; and
detecting an error status of the device information stored in the memory circuit, based on a level difference of the first verify voltage and the second verify voltage.

2. The method of claim 1, further comprising storing the device information in a plurality of latch circuits of the memory circuit.

3. The method of claim 1, wherein the device information includes information about a first default level and a first offset level corresponding to the first verify voltage, and information about a second default level and a second offset level corresponding to the second verify voltage, and
wherein the method further comprises generating the first verify voltage based on the information about the first default level and the first offset level, and generating the second verify voltage based on the information about the second default level and the second offset level.

4. The method of claim 1, wherein the applying of the first verify voltage and the second verify voltage to the selected word line and the detecting of error status of the device information stored in the memory circuit based on the level difference are performed in parallel.

5. The method of claim 1, wherein, further comprising setting the error status to indicate an error has occurred based on the level difference of the first verify voltage and the second verify voltage being outside of a reference range.

6. The method of claim 5, further comprising performing a refresh operation on the memory circuit under control of the controller based on the error status indicating the error.

7. The method of claim 6, further comprising:
after the refresh operation on the memory circuit is performed, again receiving the program command, the address, and the data from the controller; and
again performing the program operation on the selected word line according to the program command received after the refresh operation on the memory circuit is performed.

8. The method of claim 1, further comprising determining a pass state of the program operation based on the level difference of the first verify voltage and the second verify voltage being inside of a reference range.

9. The method of claim 8, further comprising storing status information, based on the error status and the pass state.

10. The method of claim 9, further comprising:
receiving a status read command from the controller; and
transmitting the status information to the controller in response to the status read command.

11. A memory device comprising:
a memory circuit configured to store device information;
a memory cell array comprising a plurality of memory cells connected to a plurality of word lines;
a control logic circuit configured to generate a first verify code and a second verify code, based on the device information, during a program verify operation;
a voltage generating circuit configured to generate a first verify voltage based on the first verify code and generate a second verify voltage based on the second verify code, during the program verify operation;
a row address decoder configured to apply the first verify voltage and the second verify voltage to a selected word line among the plurality of word lines, during the program verify operation; and
an error checker circuit configured to detect an error status of the device information, based on a level difference of the first verify code and the second verify code, during the program verify operation.

12. The memory device of claim 11, wherein the memory circuit comprises a plurality of latch circuits configured to store the device information.

13. The memory device of claim 11, wherein the error checker circuit comprises:
a first register configured to store the first verify code;
a second register configured to store the second verify code;
a delta code generator circuit configured to generate a delta code corresponding the level difference of the first verify code stored in the first register and the second verify code stored in the second register;
a reference range generator circuit configured to generate a maximum reference value and a minimum reference value, based on the device information; and
a comparator configured to identify a comparison result by determining whether the delta code is greater than the maximum reference value and determining whether the delta code is smaller than the minimum reference value, and to output the error status based on the comparison result.

14. The memory device of claim 11, further comprising a pass/fail checker circuit configured to determine a pass state of a program operation, based on a first cell counting value and a second cell counting value,
wherein the first cell counting value is obtained by counting first memory cells, which are determined based on the first verify voltage, from among memory cells connected to the selected word line, and
wherein the second cell counting value is obtained by counting second memory cells, which are determined based on the second verify voltage, from among the memory cells connected to the selected word line.

15. The memory device of claim 14, wherein the control logic circuit is further configured to set status information, based on the error status detected by the error checker circuit and the pass state determined by the pass/fail checker circuit.

16. A method of operating a memory device which includes a memory circuit, the method comprising:
receiving a program command, an address, and data from a controller; and
sequentially performing a plurality of program loops on a selected word line corresponding to the address to perform a program operation of storing the data, according to the program command,
wherein each of the plurality of program loops comprises:
applying a program voltage to the selected word line to control threshold voltages of selected memory cells connected to the selected word line;
applying verify voltages to the selected word line to verify a program state of the selected memory cells; and
detecting an error status of device information stored in the memory circuit, based on a level difference of the verify voltages.

17. The method of claim 16, wherein the device information includes information about a default level and information about an offset level, for each of the verify voltages, and
wherein the method further comprises generating the verify voltages based on the information about the default level and the information about the offset level.

18. The method of claim 16, further comprising setting the error status to indicate than an error occurs in the device information based on the level difference of the verify voltages being out of a reference range.

19. The method of claim 18, further comprising stopping execution of remaining program loops among the plurality of program loops based on the error status indicating that the error occurs.

20. The method of claim 16, further comprising determining a pass state of the program operation based on the level difference being inside of a reference range.
